(19) United States
(12) Patent Application Publication
(10) Pub. No.: US 2025/0143072 A1
(43) Pub. Date: May 1, 2025

(54) AMORPHOUS METAL BASED TOP EMISSION ORGANIC LIGHT EMITTING DIODES

(71) Applicant: Amorphyx, Incorporated, Corvallis, OR (US)

(72) Inventor: Sean William MUIR, Corvallis, OR (US)

(73) Assignee: Amorphyx, Incorporated, Corvallis, OR (US)

(21) Appl. No.: 18/837,057

(22) PCT Filed: Feb. 14, 2023
(86) PCT No.: PCT/US2023/062559

§ 371 Date: Aug. 8, 2024

Related U.S. Application Data
(60) Provisional application No. 63/311,783, filed on Feb. 18, 2022.

(51) Int. Cl. H10K 50/818; H10K 50/82; H10K 102/00; H10K 102/20

(52) U.S. Cl. CPC H10K 50/818; H10K 50/82; H10K 2102/20; H10K 2102/3026

(57) ABSTRACT

The present disclosure is directed to an organic light emitting diode (OLED) that includes a first electrode that is an amorphous metal electrode. A first transport layer is on the first electrode, an emission layer is on the first transport layer, a second transport layer is on the emission layer, and a second electrode is on the second transport layer. The amorphous metal electrode provides a smooth, even surface such that the first transport layer, the emission layer, the second transport layer, and the second electrode are also formed evenly.

### BACKGROUND

### Technical Field

The present disclosure is directed to organic light emitting diodes with amorphous metals.

### Description of the Related Art

Organic light emitting diodes (OLED) are often used to create displays for electronic devices, such as computers, monitors, televisions, tablets, and mobile devices. OLEDs generally have a stack of layers including an organic emission layer positioned between an anode and a cathode. The organic emission layer emits light in response to an electrical signal being applied to the organic emission layer via the anode and cathode. OLEDs typically have either a bottom emission structure or a top emission structure.

Bottom emission OLEDs include a transparent anode as a bottom electrode of the OLED stack. In this case, light is transmitted from the emission layer and through the transparent anode. In contrast, top emission OLEDs include a reflective anode as a bottom electrode of the OLED stack, and a transparent cathode as a top electrode of the OLED stack. In this case, light is transmitted from the emission layer and through the transparent cathode. Light is also reflected from the reflective anode and through the transparent cathode. Top emission OLEDs may also be inverted in which the OLED stack includes a reflective cathode as a bottom electrode, and a transparent anode as a top electrode. In this case, light is transmitted from the emission layer and through the transparent anode. Light is also reflected from the reflective cathode and through the transparent anode.

Top emission electrodes are particularly desirable for flat panel displays, such as active matrix OLED (AMOLED) displays, because light emits away from the substrate carrying the OLED stack and other circuitry on or in the substrate. This allows the OLED to utilize more of a given pixel area and have a larger aperture ratio. Utilizing more area of a pixel results in brighter displays for a given resolution, and higher resolution for a given brightness.

Various metals, such as aluminum (Al) and indium tin oxide (ITO), are commonly used as the electrodes for OLEDs. However, the surface morphology of such metals are difficult to control during fabrication. Consequently, the electrodes often have rough, uneven surfaces. As subsequent layers are deposited on an electrode, the surface morphology of the electrode are directly transferred to the surface morphology of the subsequent layers. The rough surface of the hole injecting electrode (e.g., the reflective anode of a top emission OLED and the reflective cathode of an inverted top emission OLED) is particularly important as the rough surface results in irregularities in the organic emission layer deposited on the hole injecting electrode. Irregularities in the organic emission layer may cause significant negative effects on the OLED, itself, such as degradation and dark spot formations.

### BRIEF SUMMARY

The present disclosure is directed to an organic light emitting diode (OLED) with one or more amorphous metal electrodes. The amorphous metal electrode provides a smooth, even surface for subsequent layers to be formed on the amorphous metal electrode. The OLED may be, for example, a top emission OLED and an inverted top emission OLED.

In a top emission OLED, the OLED includes a substrate, an anode on the substrate, a hole transport layer on the anode, an organic emission layer on the hole transport layer, an electron transport layer on the organic emission layer, and a cathode on the electron transport layer. The anode is a reflective, amorphous metal with a high work function (e.g., between 4.5 and 5 eV), and the cathode is transparent and has a low work function (e.g., between 4 and 4.4 eV).

In an inverted top emission OLED, the OLED includes a substrate, a cathode on the substrate, an electron transport layer on the cathode, an organic emission layer on the electron transport layer, a hole transport layer on the organic emission layer, a hole transport layer on the organic emission layer, and an anode on the hole transport layer. The cathode is a reflective, amorphous metal with a low work function (e.g., between 4 and 4.4 eV), and the anode 14 is transparent and has a high work function (e.g., between 4.5 and 5 eV).

Various other layers, such as injection and blocking layers, may also be included in the OLED.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale.

FIG. 1 is a cross sectional view of an organic light emitting diode with an amorphous anode according to an embodiment disclosed herein.

FIG. 2 is a surface of a metal layer according to an embodiment disclosed herein.

FIG. 3 is a surface of an amorphous metal layer according to an embodiment disclosed herein.

FIG. 4 is a cross sectional view of an organic light emitting diode with an amorphous cathode according to an embodiment disclosed herein.

FIG. 5 is a cross sectional view of an organic light emitting diode according to an embodiment disclosed herein.

FIG. 6 is a cross sectional view of an organic light emitting diode according to an embodiment disclosed herein.

FIG. 7 is a cross sectional view of an organic light emitting diode according to an embodiment disclosed herein.

FIG. 8 is a cross sectional view of an organic light emitting diode according to an embodiment disclosed herein.

### DETAILED DESCRIPTION

In the following description, certain specific details are set forth in order to provide a thorough understanding of various aspects of the disclosed subject matter. However, the disclosed subject matter may be practiced without these specific details. In some instances, well-known structures and methods of manufacturing and operation of electronic components and organic light emitting diodes (OLED) have not been described in detail to avoid obscuring the descriptions of other aspects of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

Reference throughout the specification to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same aspect. Furthermore, the particular features, structures, or characteristics may be combined in any suitable manner in one or more aspects of the present disclosure.

As discussed above, the surface morphology of metals typically used for electrodes of OLEDs, such as aluminum (Al) and Indium tin oxide (ITO), are difficult to control during fabrication, and often have rough, uneven surfaces. As subsequent layers are deposited on the rough surfaces of the electrode, the surface morphology of the electrode cause the subsequent layers to have rough, uneven surfaces. Such irregularities in the organic emission layer are particularly harmful as they may cause degradation and dark spot formations in the OLED.

The present disclosure is directed to OLEDs with one or more amorphous metal electrodes, and methods for fabricating the same. The amorphous metal electrode provides a smooth, even surface for subsequent layers subsequently formed on the amorphous metal electrode. As a result, subsequent layers, such as an organic emission layer, are formed evenly on the amorphous metal electrode, and degradation and dark spot formations in the OLED are minimized.

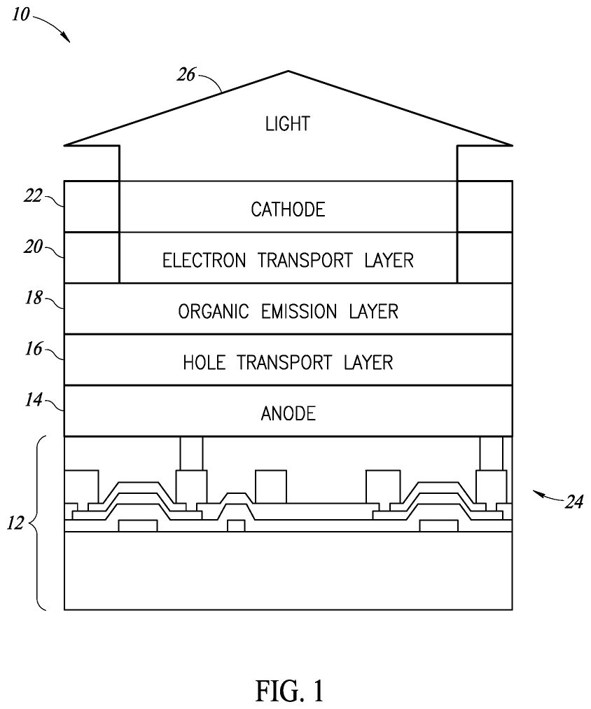

FIG. 1 is a cross sectional view of an OLED 10 with an amorphous anode according to an embodiment disclosed herein. The OLED 10 is a top emission OLED. The OLED 10 includes a substrate 12, an anode 14, a hole transport layer 16, an organic emission layer 18, an electron transport layer 20, and a cathode 22.

The substrate 12 provides a supporting layer for the anode 14, the hole transport layer 16, the organic emission layer 18, the electron transport layer 20, and the cathode 22. In one embodiment, the substrate 12 is a semiconductor substrate. In one embodiment, the substrate 12 is transparent, and is made of, for example, glass. The substrate may be any suitable transparent material, such as plastic. In addition, the substrate may be bendable, flexible, or otherwise not rigid such that a resulting display can be rolled or bent without damaging the electronic components.

In one embodiment, as shown in FIG. 1, the substrate 12 may include circuitry 24 for the OLED 10. The circuitry 24 may include various electronic components (e.g., resistors, transistors, capacitors, etc.), electrical connections, addressing circuitry, and driving circuitry for the OLED 10. The circuitry 24 may also be fabricated on another substrate, and be electrically coupled to the OLED 10 through electrical connections.

The anode 14 is formed on the substrate 12. The anode 14 is a bottom electrode and serves as a base for subsequent layers. In one embodiment, the anode 14 is in direct contact with the substrate 12. The anode 14 is an anode electrode of the OLED 10 that is positively charged by, for example, the circuitry 24 in order to inject holes into the organic emission layer 18.

The anode 14 is made of a reflective material, and reflects light generated by the organic emission layer 18 back towards the organic emission layer 18 and out of the cathode 22. The anode 14 also has a high work function. The work function, for example, indicates the amount of energy used to remove an electron from the metal. In one embodiment, the anode 14 has a work function that is between 4.5 and 5 electron volts (eV).

The anode 14 is made of an amorphous metal. Amorphous metals are rigid solid materials whose atomic structure lacks periodicity that characterizes crystalline materials. In an amorphous metal, formation of crystalline planes is suppressed, for example, by incorporating a plurality of components. Alternatively, this can be achieved with binary systems. Amorphous metals are often formed by fast quenching from a metal melt, or from a plasma by physical vapor deposition (i.e., sputtering). Having more elements can help enable slower quench speeds from melts; however, when using a physical vapor deposition (PVD) from a plasma, quench speeds can be high enough that multiple elements are not as crucial. Even in a binary system, the elements can have very different sizes. An example of an amorphous metal having four components is Zr₅₅Cu₃₀Al₁₀Ni₅, which includes zirconium, copper, aluminum, and nickel.

Amorphous metals can be identified by their resistivity measurements, which have shown that an amorphous metal material, while still conductive, has about ten times greater resistivity than its crystalline counterpart. Further, amorphous metals are desirable for electrodes of OLEDs used in flexible OLED displays as amorphous metals are inherently strong and flexible.

In addition, amorphous metals have a wide range of work functions. For example, amorphous calcium aluminate electride has an approximate work function of 3 eV, amorphous zinc silicate has an approximate work function of 3.5 eV, an amorphous metal Ta₄₀W₄₀Si₁₀B₁₀ has an approximate work function of 4.1, amorphous metal TiAl₃ has an approximate work function of 4.3, and amorphous metal Zr₄₀Cu₃₅Al₁₅Ni₁₀ has an approximate work function of 4.7. As such, as will be discussed in further detail below, amorphous metal may also be used for a cathode, which generally has a low work function.

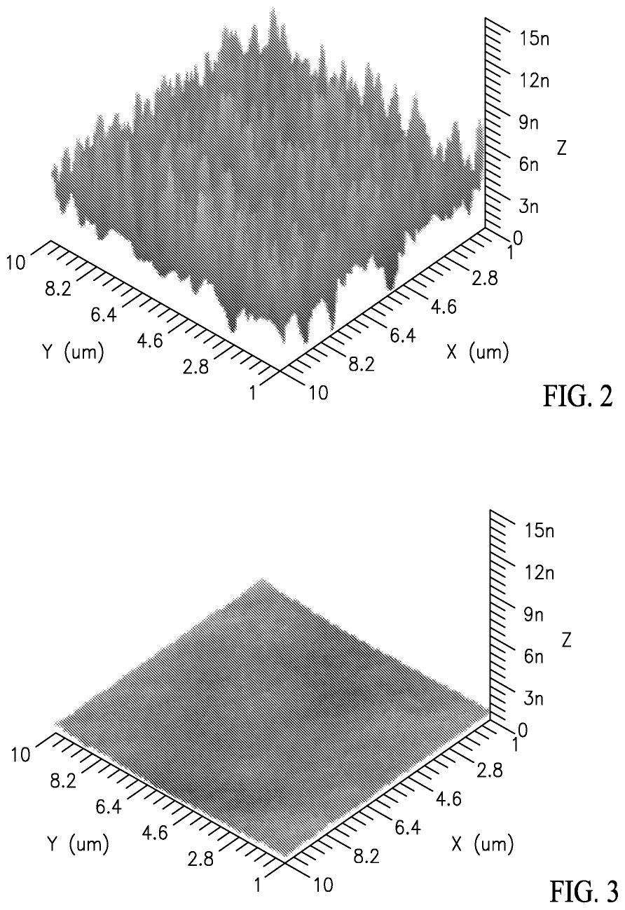

Amorphous metals also have smoother surfaces than crystalline metals, as indicated by surface roughness measurements. For example, FIG. 2 is a surface of a metal layer according to an embodiment disclosed herein, and FIG. 3 is a surface of an amorphous metal layer according to an embodiment disclosed herein. The metal layer is aluminum in FIG. 2, and the amorphous metal layer is amorphous metal TiAl₃ in FIG. 3. The surfaces shown in FIGS. 2 and 3 are shown along a y-axis in micrometers, an x-axis in micrometers, and a z-axis in meters.

Comparing FIGS. 2 and 3, it can be seen that the amorphous metal layer provides a much smoother, even surface than the metal layer. For example, the metal layer in FIG. 2 has a root mean square roughness greater than 3 nanometers. In contrast, the amorphous metal layer in FIG. 3 has a root mean square roughness less than 1 nanometer.

Using amorphous metal for the anode 14 provides a smooth, flexible foundational layer to build subsequent layers (the hole transport layer 16, the organic emission layer 18, the electron transport layer 20, and the cathode 22). As a result, the subsequent layers are formed evenly on the amorphous metal surface, and degradation and dark spot formations in the OLED 10 are minimized. This also enables improved reliability of devices containing the OLED 10, and flexible OLED displays with higher aperture ratio.

In one embodiment, the anode 14 has a root mean square roughness between 0.5 and 1 nanometer.

In one embodiment, the anode 14 includes amorphous metal Zr₄₀Cu₃₅Al₁₅Ni₁₀. Amorphous metals other than Zr₄₀Cu₃₅Al₁₅Ni₁₀ may also be used, as well as other materials in combination with amorphous metals, to better tune the electrode surface properties. Typically, mixing and matching of materials is done with the cathode, to lower the cathode's effective work function, and not with the anode.

The hole transport layer 16 is formed on the anode 14. The hole transport layer 16 transports holes from the anode 14 and to the organic emission layer 18.

The organic emission layer 18 is formed on the anode 14. The organic emission layer 18 converts electrical energy generated by the holes from the anode 14 into light. The organic emission layer 18 is, for example, made from a host material plus a dopant to control a specific color. For example, the organic emission layer 18 may emit red, green, blue, or white light depending on the application of the OLED 10.

The electron transport layer 20 is formed on the organic emission layer 18. The electron transport layer 20 transports electrons from the cathode 22, which will be discussed below, to the organic emission layer 18.

The cathode 22 is formed on the electron transport layer 20. The cathode 22 is a cathode electrode of the OLED 10 that is negatively charged by, for example, the circuitry 24 in order to inject electrons into the organic emission layer 18.

In contrast to the anode 14, the cathode 22 is made of a transparent material such that light 26 generated by the organic emission layer 18 is emitted through the electron transport layer 20 and out of the cathode 22. Further, the cathode 22 has a low work function. In one embodiment, the cathode 22 has a work function that is between 4 and 4.4 eV.

Metals with low work function are typically more chemically reactive and less stable. Due to this instability, in some embodiments, the cathode 22 is coated with a less reactive, slightly higher work function material, such as aluminum.

The anode 14 and the cathode 22 may be made of of the same or different materials. For example, in the embodiment shown in FIG. 1, the anode 14 and the cathode 22 are both amorphous metals as discussed above. As another example, the anode 14 is an amorphous metal as discussed above; and the cathode 22 is a non-amorphous metal, such as aluminum, magnesium silver, lithium fluoride, and indium tin oxide.

As mentioned above, amorphous metals have a wide range of work functions. For example, amorphous calcium aluminate electride has an approximate work function of 3 eV, amorphous zinc silicate has an approximate work function of 3.5 eV, an amorphous metal Ta₄₀W₄₀Si₁₀B₁₀ has an approximate work function of 4.1, amorphous metal TiAl₃ has an approximate work function of 4.3, and amorphous metal Zr₄₀Cu₃₅Al₁₅Ni₁₀ has an approximate work function of 4.7. As such, amorphous metal may also be used for a cathode, which generally has a low work function.

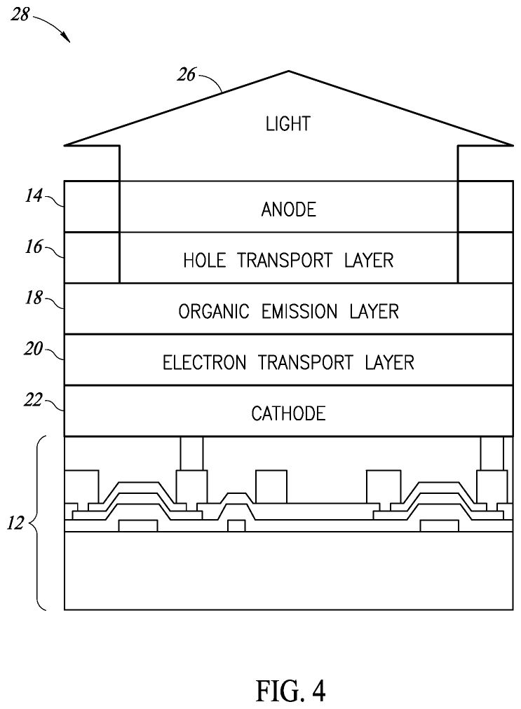

FIG. 4 is a cross sectional view of an OLED 28 with an amorphous cathode according to an embodiment disclosed herein. Similar to the OLED 10 in FIG. 1, the OLED 28 includes the substrate 12, the anode 14, the hole transport layer 16, the organic emission layer 18, the electron transport layer 20, and the cathode 22. Further, the anode 14 has a high work function (e.g., between 4.5 and 5 eV), and the cathode 22 has a low work function (e.g., between 4 and 4.4 eV).

In contrast to the OLED 10, the OLED 28 is an inverted top emission OLED, and the layers on the substrate 12 are inverted. Stated differently, the cathode 22 is formed on the substrate 12, the electron transport layer 20 is formed on the cathode 22, the organic emission layer 18 is formed on the electron transport layer 20, the hole transport layer 16 is formed on the organic emission layer 18, and the anode 14 is formed on the hole transport layer 16. As such, the light 26 is generated by the organic emission layer 18 and is emitted through the hole transport layer 16 and out of the anode 14. In this embodiment, cathode 22 is a bottom electrode and serves as a base for subsequent layers. In one embodiment, the cathode 22 in direct contact with the substrate 12.

In addition, the cathode 22 in the OLED 28 is made of a reflective material, and reflects light generated by the organic emission layer 18 back towards the organic emission layer 18 and out of the anode 14. Further, the cathode 22 is made of an amorphous metal. As discussed above, using amorphous metal for the cathode 22 provides a smooth, flexible foundational layer to build subsequent layers (the electron transport layer 20, the organic emission layer 18, the hole transport layer 16, and the anode 14). As a result, the subsequent layers are formed evenly on the amorphous metal surface, and degradation and dark spot formations in the OLED 28 are minimized.

In one embodiment, the cathode 22 includes one of amorphous metal TiAl₃, amorphous metal Ta₄₀Si₄₀W₁₀B₁₀, or a combination thereof. Amorphous metals other than TiAl₃ and Ta₄₀Si₄₀W₁₀B₁₀ may also be used, as well as other materials in combination with amorphous metals, to better tune the surface properties of the cathode, such as electrode work function. For example, in one embodiment, a capping layer is formed between the cathode 22 and the electron transport layer 20. The capping layer may include one of lithium fluoride (LiF), amorphous calcium aluminate electride, amorphous zinc silicate, or a combination thereof.

Also in contrast to the OLED 10, the anode 14 in the OLED 28 is made of a transparent material such that light 26 generated by the organic emission layer 18 is emitted through the hole transport layer 16 and out of the anode 14.

As discussed above, the anode 14 and the cathode 22 may be made of of the same or different materials. For example, in the embodiment shown in FIG. 4, the anode 14 and the cathode 22 may both be amorphous metals as discussed above. As another example, the cathode 22 is an amorphous metal; and the anode 14 is a non-amorphous metal, such as aluminum, magnesium silver, lithium fluoride, and indium tin oxide.

Amorphous metal OLEDs, such as the OLED 10 and the OLED 28 discussed above, are not limited to specific materials, specific layer combinations, or specific material thicknesses for any of the functional layers placed on top of the foundational amorphous metal anode or cathode. The specific materials and thicknesses chosen for the anode, hole transport layer, organic emission layer, electron transport layer, and cathode discussed above depend on the application (e.g., flat panel display, lighting, flexible display, etc.). Amorphous metal OLEDs may also include additional functional layers, such as injection and blocking layers, to enhance performance.

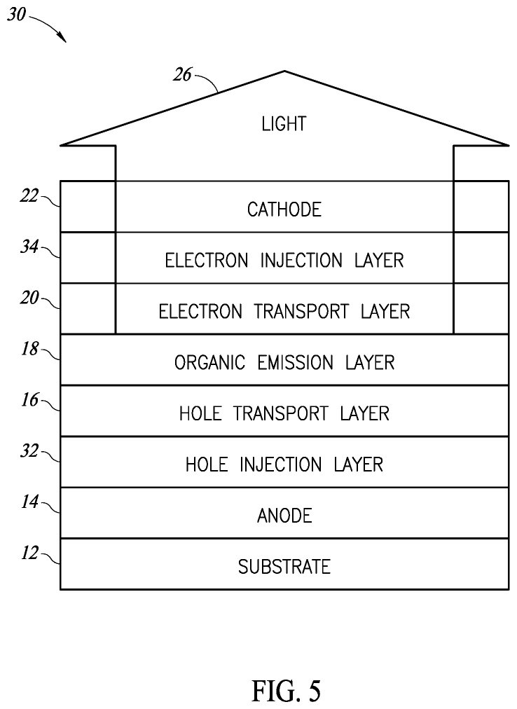

FIGS. 5 to 8 below show examples of other OLEDs including a foundational amorphous metal anode or cathode.

FIG. 5 is a cross sectional view of an OLED 30 according to an embodiment disclosed herein. Similar to the OLED 10 in FIG. 1, the OLED 30 is a top emission OLED; and includes the substrate 12, the anode 14, the hole transport layer 16, the organic emission layer 18, the electron transport layer 20, and the cathode 22. Further, the anode 14 is a reflective, amorphous metal with a high work function (e.g., between 4.5 and 5 eV), and the cathode 22 is transparent and has a low work function (e.g., between 4 and 4.4 eV).

In contrast to the OLED 10, the OLED 30 includes a hole injection layer 32 and an electron injection layer 34.

The hole injection layer 32 is formed between the anode 14 and the hole transport layer 16. The hole injection layer 32 improves efficiency of injection of holes from the anode 14 to the hole transport layer 16.

The electron injection layer 34 is formed between the electron transport layer 20 and the cathode 22. The electron injection layer 34 improves efficiency of injection of electrons from the cathode 22 to the electron transport layer 20.

In one embodiment, referring to the OLED 30 shown in FIG. 5, the substrate 12 includes glass; the anode 14 includes amorphous metal Zr₄₀Cu₃₅Al₁₅Ni₁₀; the hole injection layer 32 includes non-stoichiometric molybdenum oxide (MoOₓ); the hole transport layer 16 includes N,N′-di(1-naphthyl)-N,N′-diphenyl-(1,1′-biphenyl)-4,4′-diamine (NPD); the organic emission layer 18 includes 4,4′-Bis(N-carbazolyl)-1,1′-biphenyl doped with Tris[2-phenylpyridinato-C²,N]iridium(III) (CPB:Ir(ppy)3), which acts as a white light emitter; the electron transport layer 20 includes Tris-(8-hydroxyquinoline) aluminum (Alq); the electron injection layer 34 includes a first sublayer having amorphous zinc silicate (a-ZSO) and a second sublayer having amorphous calcium aluminate electride (a-C12A7:e); and the cathode 22 includes aluminum (Al).

In one embodiment, referring to the OLED 30 shown in FIG. 5, the substrate 12 has a thickness between 0.1 and 1.15 millimeters, the anode 14 has a thickness between 25 and 300 nanometers, the hole injection layer 32 has a thickness between 2 and 20 nanometers, the hole transport layer 16 has a thickness between 20 and 400 nanometers, the organic emission layer 18 has a thickness between 20 and 100 nanometers, the electron transport layer 20 has a thickness between 20 and 400 nanometers, the first sublayer of the electron injection layer 34 has a thickness between 20 and 75 nanometers, the second sublayer of the electron injection layer 34 has a thickness between 2 and 10 nanometers, and the cathode 22 has a thickness between 10 and 25 nanometers.

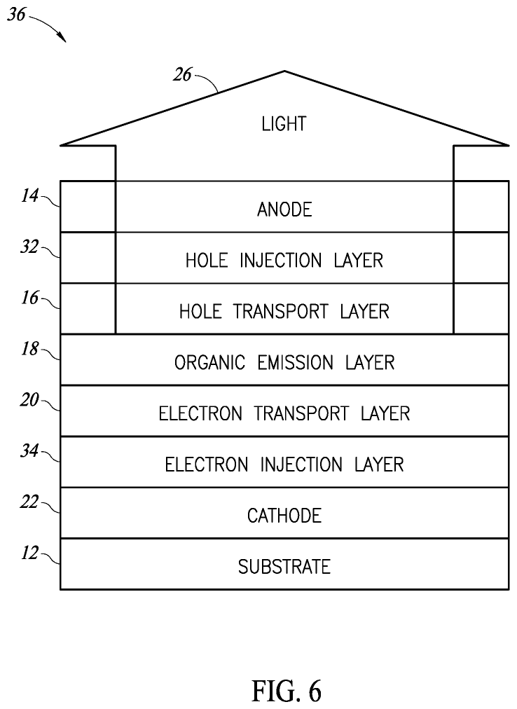

FIG. 6 is a cross sectional view of an OLED 36 according to an embodiment disclosed herein. Similar to the OLED 28 in FIG. 4, the OLED 36 is an inverted top emission OLED; and includes the substrate 12, the cathode 22, the electron transport layer 20, the organic emission layer 18, the hole transport layer 16, and the anode 14. Further, the cathode 22 is a reflective, amorphous metal with a low work function (e.g., between 4 and 4.4 eV), and the anode 14 is transparent and has a high work function (e.g., between 4.5 and 5 eV).

In contrast to the OLED 28, the OLED 36 includes the hole injection layer 32 and the electron injection layer 34, which are discussed above.

In one embodiment, referring to the OLED 36 shown in FIG. 6, the substrate 12 includes glass; the cathode 22 includes amorphous metal Ta₄₀Si₄₀W₁₀B₁₀; the electron injection layer 34 includes a first sublayer having amorphous zinc silicate (a-ZSO) and a second sublayer having amorphous calcium aluminate electride (a-C12A7:e); the electron transport layer 20 includes Tris-(8-hydroxyquinoline)aluminum (Alq); the organic emission layer 18 includes Tris-(8-hydroxyquinoline)aluminum doped with 1,1,4,4-Tetraphenyl-1,3-butadiene (Alq:TPB), which acts as a blue light emitter; the hole transport layer 16 includes N,N′-di(1-naphthyl)-N,N′-diphenyl-(1,1′-biphenyl)-4,4′-diamine (NPD); the hole injection layer 32 includes non-stoichiometric molybdenum oxide (MoOₓ); the anode 14 includes indium tin oxide (ITO).

In one embodiment, referring to the OLED 36 shown in FIG. 6, the substrate 12 has a thickness between 0.1 and 1.15 millimeters, the cathode 22 has a thickness between 25 and 300 nanometers, the first sublayer of the electron injection layer 34 has a thickness between 20 and 75 nanometers, the second sublayer of the electron injection layer 34 has a thickness between 2 and 10 nanometers, the electron transport layer 20 has a thickness between 20 and 400 nanometers, the organic emission layer 18 has a thickness between 20 and 100 nanometers, the hole transport layer 16 has a thickness between 20 and 400 nanometers, the hole injection layer 32 has a thickness between 2 and 20 nanometers, and the anode 14 has a thickness between 25 and 200 nanometers.

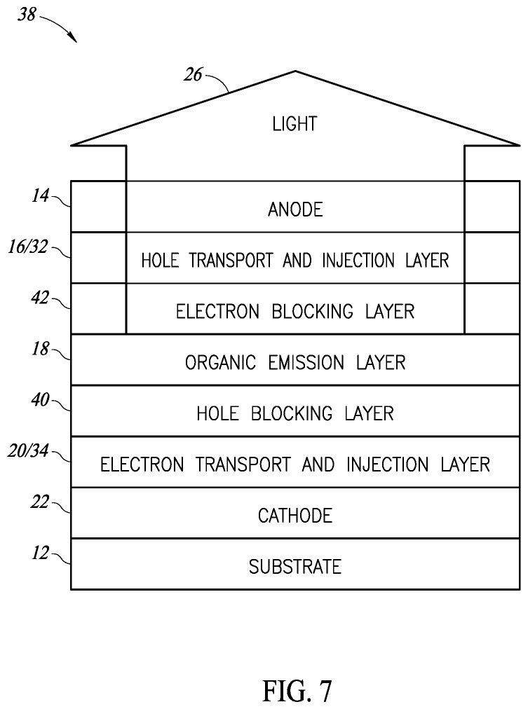

FIG. 7 is a cross sectional view of an OLED 38 according to an embodiment disclosed herein. Similar to the OLED 28 in FIG. 4, the OLED 38 is an inverted top emission OLED; and includes the substrate 12, the cathode 22, the electron transport layer 20, the organic emission layer 18, the hole transport layer 16, and the anode 14. Further, the cathode 22 is a reflective, amorphous metal with a low work function (e.g., between 4 and 4.4 eV), and the anode 14 is transparent and has a high work function (e.g., between 4.5 and 5 eV).

In contrast to the OLED 28, the OLED 38 includes the hole injection layer 32 and the electron injection layer 34, which are discussed above. Further, the hole injection layer 32 and the hole transport layer 16 are implemented with the same layer, and the electron injection layer 34 and the electron transport layer 20 are implemented with the same layer. Stated differently, the same material may act as the hole injection layer 32 and the hole transport layer 16, and the same material may act as the electron injection layer 34 and the electron transport layer 20.

In addition, the OLED 38 includes a hole blocking layer 40 and an electron blocking layer 42.

The hole blocking layer 40 is formed between the electron transport and injection layer 20/34 and the organic emission layer 18. The hole blocking layer 40 confines charge carriers to the organic emission layer 18.

The electron blocking layer 42 is formed between the organic emission layer 18 and the hole transport and injection layer 16/32. The electron blocking layer 42 confines charge carriers to the organic emission layer 18.

In one embodiment, referring to the OLED 38 shown in FIG. 7, the substrate 12 includes glass; the cathode 22 includes amorphous metal TiAl3; the electron transport and injection layer 20/34 includes 4,7-diphenyl-1,10-phenanthroline doped with Cs (BPhen:Cs); the hole blocking layer 40 includes 4,7-diphenyl-1,10-phenanthroline (BPhen); the organic emission layer 18 includes 2,2′-Dimethyl-N,N′-di-[(1-naphthyl)-N, N′-diphenyl]-1,1′-biphenyl-4,4′-diamine doped with iridium(III)bis(2-methyldibenzo-[f,h]chinoxalin)(acetylacetonat) (α-NPD:Ir(MDQ)₂(acac)), which acts as a white light emitter; the electron blocking layer 42 includes 2,2′-Dimethyl-N,N′-di-[(1-naphthyl)-N, N′-diphenyl]-1,1′-biphenyl-4,4′-diamine (α-NPD); the hole transport and injection layer 16/32 includes N,N,N′,N′-tetrakis (4-methoxyphenyl)-benzidine doped with Novaled dopant p-type 2 (MeO-TBD+NDP-2); and the anode 14 includes gold (Au).

In one embodiment, referring to the OLED 38 shown in FIG. 7, the substrate 12 has a thickness between 0.1 and 1.15 millimeters, the cathode 22 has a thickness between 25 and 300 nanometers, the electron transport and injection layer 20/34 has a thickness between 20 and 400 nanometers, the hole blocking layer 40 has a thickness between 20 and 100 nanometers, the organic emission layer 18 has a thickness between 20 and 100 nanometers, the electron blocking layer 42 has a thickness between 20 and 100 nanometers, the hole transport and injection layer 16/32 has a thickness between 20 and 400 nanometers, and the anode 14 has a thickness between 10 and 25 nanometers.

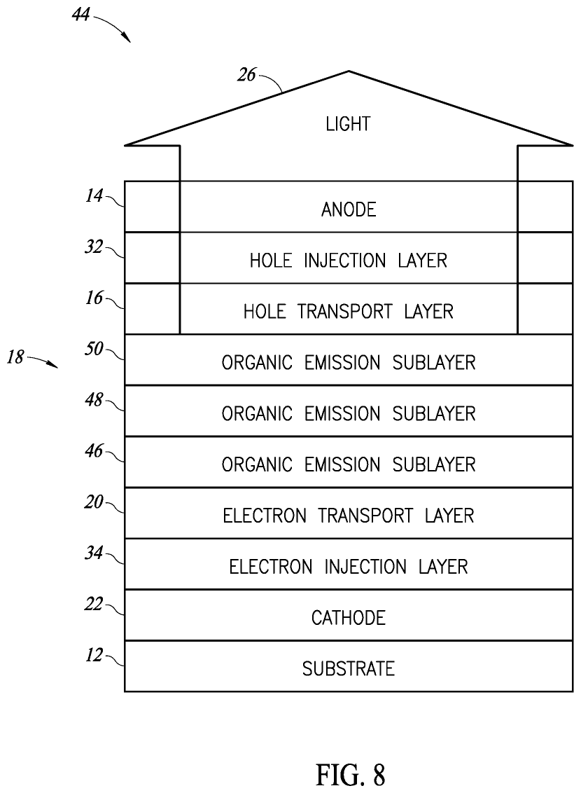

FIG. 8 is a cross sectional view of an OLED 44 according to an embodiment disclosed herein. Similar to the OLED 36 in FIG. 6, the OLED 44 is an inverted top emission OLED; and includes the substrate 12, the cathode 22, the electron injection layer 34, the electron transport layer 20, the organic emission layer 18, the hole transport layer 16, the hole injection layer 32, and the anode 14. Further, the cathode 22 is a reflective, amorphous metal with a low work function (e.g., between 4 and 4.4 eV), and the anode 14 is transparent and has a high work function (e.g., between 4.5 and 5 eV).

In contrast to the OLED 36, the organic emission layer 18 of the OLED 44 includes a first sublayer 46, a second sublayer 48, and a third sublayer 50. In addition, the anode 14 is made of an amorphous metal.

In one embodiment, referring to the OLED 44 shown in FIG. 8, the substrate 12 includes glass; the cathode 22 includes amorphous metal TiAl₃; the electron injection layer 34 includes lithium fluoride (LiF); the electron transport layer 20 includes 3-(4-biphenyl)-4-phenyl-5-(4-tert-butylphenyl)-1, 2,4-triazole (TAZ); the first sublayer 46 includes 1,3-bis(9-carbazolyl) benzene doped with bis (2,4-diphenylquinolyl-N, C²′)iridium(acetylacetonate)(mCP:(PPQ)₂Ir (acac)), which acts as a red light emitter; the second sublayer 48 includes 1,3-bis(9-carbazolyl)benzene doped with Tris[2-phenylpyridinato-C², N]iridium(III)(mCP:Ir(ppy)₃), which acts as a green light emitter; the third sublayer 50 includes 1,3-bis(9-carbazolyl)benzene doped with iridium(III) bis[(4,6-difluorophenyl)-pyridinato-N,C²′]picolinate (mCP:Firpic), which acts as a blue light emitter; the hole transport layer 16 includes 4,4-bis(N-(1-naphthyl)-N-phenylamino) biphenyl (NPB); the hole injection layer 32 includes non-stoichiometric molybdenum oxide (MoOₓ); the anode 14 includes amorphous metal Zr₄₀Cu₃₅Al₁₅Ni₁₀.

In one embodiment, referring to the OLED 44 shown in FIG. 8, the substrate 12 has a thickness between 0.1 and 1.15 millimeters, the cathode 22 has a thickness between 25 and 300 nanometers, the electron injection layer 34 has a thickness between 2 and 20 nanometers, the electron transport layer 20 has a thickness between 20 and 400 nanometers, the first sublayer 46 has a thickness between 20 and 100 nanometers, the second sublayer 48 has a thickness between 20 and 100 nanometers, the third sublayer 50 has a thickness between 20 and 100 nanometers, the hole transport layer 16 has a thickness between 20 and 400 nanometers, the hole injection layer 32 has a thickness between 2 and 20 nanometers, and the anode 14 has a thickness between 10 and 25 nanometers.

The various layers of the OLEDs discussed herein may not be distinct materials. For example, a single material may act as an electron transport layer as well as an organic emission layer. Alternatively, one or more materials may be used to form a single layer.

The present disclosure focuses on top emission OLEDs and inverted top emission OLEDs with amorphous metal electrodes as the amorphous metal electrodes are particularly useful for structures with a stack of layers formed on the electrode. However, the amorphous metal electrodes discussed herein may be employed in other types of OLEDs that include a stack layers formed on top of an electrode.

The various embodiments disclosed herein provide OLEDs with one or more amorphous metal electrodes, and methods for fabricating the same. The amorphous metal electrode provides a smooth, even surface such that subsequent layers on the surface of the amorphous metal electrode are also formed smooth and evenly.

A device may be summarized as including: a substrate; a first electrode on the substrate, the first electrode including an amorphous metal; a first transport layer on the first electrode; an emission layer on the first transport layer; a second transport layer on the emission layer; and a second electrode on the second transport layer.

The emission layer may be an organic emission layer.

The substrate may be a glass substrate.

The first electrode may be an anode; the first transport layer may be a hole transport layer; the second transport layer may be an electron transport layer; and the second electrode may be a cathode.

The anode may be reflective, and the cathode may be transparent.

The anode may have a first work function, and the cathode may have a second work function that may be smaller than the first work function.

The amorphous metal may include Zr₄₀Cu₃₅Al₁₅Ni₁₀.

The first electrode may be a cathode; the first transport layer may be an electron transport layer; the second transport layer may be a hole transport layer; and the second electrode may be an anode.

The cathode may be reflective, and the anode may be transparent.

The cathode may have a first work function, and the anode may have a second work function that may be greater than the first work function.

The amorphous metal may include a material selected from a group of materials including Ta₄₀Si₄₀W₁₀B₁₀ and TiAl₃.

The device may further include: a capping layer between the first electrode and the first transport layer.

The capping layer may include a material selected from a group of materials including lithium fluoride (LiF), amorphous calcium aluminate electride, and amorphous zinc silicate.

The second electrode may include an amorphous metal.

The device may further include: a first injection layer on the first electrode, the first transport layer being on the first injection layer; and a second injection layer on the second transport layer, the second electrode being on the second injection layer.

The first injection layer and the first transport layer may be made of the same material, and the second injection layer and the second transport layer may be made of the same material.

The first electrode may have a first thickness, and the second electrode may have a second thickness that is smaller than the first thickness.

The device may further include: a first blocking layer on the first transport layer, the emission layer being on the first blocking layer; and a second blocking layer on the emission layer, the second transport layer being on the second blocking layer.

A method may be summarized as including: forming a first electrode on a substrate, the first electrode including an amorphous metal; forming a first transport layer on the first electrode; forming an emission layer on the first transport layer; forming a second transport layer on the emission layer; and forming a second electrode on the second transport layer.

The first electrode may be an anode; the first transport layer may be a hole transport layer; the second transport layer may be an electron transport layer; and the second electrode may be a cathode.

The amorphous metal may include Zr₄₀Cu₃₅Al₁₅Ni₁₀.

The first electrode may be a cathode; the first transport layer may be an electron transport layer; the second transport layer may be a hole transport layer; and the second electrode may be an anode.

The amorphous metal may include a material selected from a group of materials including Ta₄₀Si₄₀W₁₀B₁₀ and TiAl₃.

An organic light emitting diode (OLED) may be summarized as including: a transparent substrate; a reflective electrode on the transparent substrate, the reflective electrode including an amorphous metal; a first transport layer on the reflective electrode; an emission layer on the first transport layer; a second transport layer on the emission layer; and a transparent electrode on the second transport layer.

The reflective electrode may be an anode; the first transport layer may be a hole transport layer; the second transport layer may be an electron transport layer; and the transparent electrode may be a cathode.

The amorphous metal may include Zr₄₀Cu₃₅Al₁₅Ni₁₀.

The reflective electrode may be a cathode; the first transport layer may be an electron transport layer; the second transport layer may be a hole transport layer; and the transparent electrode may be an anode.

The amorphous metal may include a material selected from a group of materials including Ta₄₀Si₄₀W₁₀B₁₀ and TiAl₃.

The reflective electrode may have a root mean square roughness between 0.5 and 1 nanometer.

The reflective electrode may be in direct contact with the transparent substrate.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate;
a first electrode on the substrate, the first electrode including an amorphous metal;
a first transport layer on the first electrode;
an emission layer on the first transport layer;
a second transport layer on the emission layer; and
a second electrode on the second transport layer.

2. The device of claim 1 wherein the emission layer is an organic emission layer.

3. The device of claim 1 wherein the substrate is a glass substrate.

4. The device of claim 1 wherein
the first electrode is an anode,
the first transport layer is a hole transport layer,
the second transport layer is an electron transport layer, and
the second electrode is a cathode.

5. The device of claim 4 wherein the anode is reflective, and the cathode is transparent.

6. The device of claim 4 wherein the anode has a first work function, and the cathode has a second work function that is smaller than the first work function.

7. The device of claim 4 wherein the amorphous metal includes Zr₄₀Cu₃₅Al₁₅Ni₁₀.

8. The device of claim 1 wherein
the first electrode is a cathode,
the first transport layer is an electron transport layer,
the second transport layer is a hole transport layer, and
the second electrode is an anode.

9. The device of claim 8 wherein the cathode is reflective, and the anode is transparent.

10. The device of claim 8 wherein the cathode has a first work function, and the anode has a second work function that is greater than the first work function.

11. The device of claim 8 wherein the amorphous metal includes a material selected from a group of materials including Ta₄₀Si₄₀W₁₀B₁₀ and TiAl₃.

12. The device of claim 8, further comprising:
a capping layer between the first electrode and the first transport layer.

13. The device of claim 12 wherein the capping layer includes a material selected from a group of materials including lithium fluoride (LiF), amorphous calcium aluminate electride, and amorphous zinc silicate.

14. The device of claim 8 wherein the second electrode includes an amorphous metal.

15. The device of claim 1, further comprising:
a first injection layer on the first electrode, the first transport layer being on the first injection layer; and
a second injection layer on the second transport layer, the second electrode being on the second injection layer.

16. The device of claim 15 wherein the first injection layer and the first transport layer are made of the same material, and the second injection layer and the second transport layer are made of the same material.

17. The device of claim 1 wherein the first electrode has a first thickness, and the second electrode has a second thickness that is smaller than the first thickness.

18. The device of claim 1, further comprising:
a first blocking layer on the first transport layer, the emission layer being on the first blocking layer; and
a second blocking layer on the emission layer, the second transport layer being on the second blocking layer.

19. A method, comprising:
forming a first electrode on a substrate, the first electrode including an amorphous metal;
forming a first transport layer on the first electrode;
forming an emission layer on the first transport layer;
forming a second transport layer on the emission layer; and
forming a second electrode on the second transport layer.

20. The method of claim 19 wherein
the first electrode is an anode,
the first transport layer is a hole transport layer,
the second transport layer is an electron transport layer, and
the second electrode is a cathode.

21. The method of claim 20 wherein the amorphous metal includes Zr₄₀Cu₃₅Al₁₅Ni₁₀.

22. The method of claim 19 wherein
the first electrode is a cathode,
the first transport layer is an electron transport layer,
the second transport layer is a hole transport layer, and
the second electrode is an anode.

23. The method of claim 22 wherein the amorphous metal includes a material selected from a group of materials including Ta₄₀Si₄₀W₁₀B₁₀ and TiAl₃.

24. An organic light emitting diode (OLED), comprising:
a transparent substrate;
a reflective electrode on the transparent substrate, the reflective electrode including an amorphous metal;
a first transport layer on the reflective electrode;
an emission layer on the first transport layer;
a second transport layer on the emission layer; and
a transparent electrode on the second transport layer.

25. The OLED of claim 24 wherein
the reflective electrode is an anode,
the first transport layer is a hole transport layer,
the second transport layer is an electron transport layer, and
the transparent electrode is a cathode.

26. The OLED of claim 25 wherein the amorphous metal includes Zr₄₀Cu₃₅Al₁₅Ni₁₀.

27. The OLED of claim 24 wherein
the reflective electrode is a cathode,
the first transport layer is an electron transport layer,
the second transport layer is a hole transport layer, and
the transparent electrode is an anode.

28. The OLED of claim 27 wherein the amorphous metal includes a material selected from a group of materials including TasoSi40W10B10 and TiAl₃.

29. The OLED of claim 24 wherein the reflective electrode has a root mean square roughness between 0.5 and 1 nanometer.

30. The OLED of claim 24 wherein the reflective electrode is in direct contact with the transparent substrate.
